(19) United States
(12) Patent Application Publication
(10) Pub. No.: US 2017/0194535 A1
(43) Pub. Date: Jul. 6, 2017

(54) WHITE LIGHT EMITTING DEVICE AND DISPLAY APPARATUS

(71) Applicant: SAMSUNG ELECTRONICS CO., LTD., Suwon-si (KR)

(72) Inventors: Jong Won PARK, Seoul (KR); Woon Seok KIM, Suwon-si (KR); Sang Hoon AHN, Suwon-si (KR); Ji Ho YOU, Seoul (KR); Chul Soo YOON, Suwon-si (KR)

(73) Assignee: SAMSUNG ELECTRONICS CO., LTD., Suwon-si (KR)

(21) Appl. No.: 15/237,806

(22) Filed: Aug. 16, 2016

(30) Foreign Application Priority Data
Jan. 5, 2016 (KR) 10-2016-0001066

(51) Int. Cl. H01L 33/50; F21V 8/00; G02F 1/1335; H01L 33/56

(52) U.S. Cl. CPC H01L 33/504; H01L 33/507; H01L 33/56; G02B 6/0015; G02F 1/133514; G02F 1/133603; G02F 2001/133614; G02F 2202/36

(57) ABSTRACT

A white light emitting device includes a blue light emitting diode emitting first light having a dominant wavelength in a range of 440 nm to 460 nm, a quantum dot disposed on a path of the emitted first light and converting a first portion of the emitted first light into green light, and a fluoride phosphor disposed on the path of the emitted first light and converting a second portion of the emitted first light into red light. The quantum dot includes a core formed of a group III-V compound and a shell formed of a group II-VI compound, and the fluoride phosphor is represented by empirical formula AₓMF_{y}:Mn⁴⁺, A being at least one selected from Li, Na, K, Rb, and Cs, M being at least one selected from Si, Ti, Zr, Hf, Ge, and Sn, and the empirical formula satisfying 2≦x≦3 and 4≦y≦7.

### CROSS-REFERENCE TO RELATED APPLICATION

This application claims priority from Korean Patent Application No. 10-2016-0001066 filed on Jan. 5, 2016, in the Korean Intellectual Property Office, the disclosure of which is incorporated herein by reference in its entirety.

### BACKGROUND

1. Field

Apparatuses consistent with example embodiments relate to a white light emitting device and a display apparatus.

2. Description of Related Art

In general, white light emitting devices are manufactured through a method of combining a blue light emitting diode (LED) with a yellow phosphor, or combining the blue LED with a red phosphor and a green phosphor. White light emitting devices are commonly used as high efficiency light sources for display devices.

There is a demand for white light emitting devices that may cover a wide color gamut based on various color standards such as display control interface (DCI), national television system committee (NTSC), and BT.2020 in the field of display technology. New white light emitting devices having improved color reproducibility may be developed.

### SUMMARY

Example embodiments provide a white light emitting device and a display apparatus that may implement a high color reproduction.

According to example embodiments, a white light emitting device comprising a blue light emitting diode (LED) emitting first light having a dominant wavelength in a range of 440 nm to 460 nm, a first wavelength-conversion material disposed on a path of the emitted first light and converting a first portion of the emitted first light into green light, and a second wavelength-conversion material disposed on the path of the emitted first light and converting a second portion of the emitted first light into red light. The first wavelength-conversion material comprises a quantum dot comprising a core formed of a group III-V compound and a shell formed of a group II-VI compound, and the second wavelength-conversion material comprises a fluoride phosphor represented by empirical formula AₓMF_{y}:Mn⁴⁺, A being at least one selected from lithium (Li), sodium (Na), potassium (K), rubidium (Rb), and caesium (Cs), M being at least one selected from silicon (Si), titanium (Ti), zirconium (Zr), hafnium (Hf), germanium (Ge), and tin (Sn), and the empirical formula satisfying 2≦x≦3 and 4≦y≦7. The white light emitting device emits white light of which a color reproduction region covers 90% or more of a display control interface region in a CIE 1931 chromaticity diagram.

According to example embodiments, a white light emitting device includes a blue LED emitting first light having a dominant wavelength in a range of 440 nm to 460 nm, a green quantum dot disposed on a path of the emitted first light and converting a first portion of the emitted first light into second light having a peak wavelength in a range of 510 nm to 550 nm and having a full width at half maximum of 45 nm or less, and a red phosphor disposed on the path of the emitted first light and converting a second portion of the emitted first light into third light having a peak wavelength in a range of 610 nm to 635 nm and having a full width at half maximum of 30 nm or less.

According to example embodiments, a display apparatus includes an image display panel comprising a color filter layer comprising red, green, and blue color filters, and a backlight disposed on the image display panel and comprising light sources. Each of the light sources comprises a blue LED emitting first light having a dominant wavelength in a range of 440 nm to 460 nm. The display apparatus further includes a green quantum dot disposed on a path of the emitted first light and converting a first portion of the emitted first light into second light having a peak wavelength in a range of 510 nm to 550 nm and having a full width at half maximum of 45 nm or less, and a red phosphor disposed on the path of the emitted first light and converting a second portion of the emitted first light into third light having a peak wavelength in a range of 610 nm to 635 nm and having a full width at half maximum of 30 nm or less. Each of the light sources emits, through the color filter layer, fourth light of which a color reproduction region covers 90% or more of a display control interface region in a CIE 1931 chromaticity diagram.

According to example embodiments, a white light emitting device includes a blue LED emitting blue light, a quantum dot disposed on a path of the emitted blue light and converting a first portion of the emitted blue light into green light, and a fluoride phosphor disposed on the path of the emitted blue light and converting a second portion of the emitted blue light into red light.

### BRIEF DESCRIPTION OF THE DRAWINGS

FIG. 1 is a schematic cross-sectional view of a white light emitting device according to example embodiments;

FIG. 2 is a graph illustrating respective photoluminescence excitation (PLE) and photoluminescence (PL) spectra of a green phosphor, employable in example embodiments;

FIG. 3 is a graph illustrating respective PLE and PL spectra of a red phosphor, employable in example embodiments;

FIG. 4 is a graph illustrating emission spectra of a white light emitting device according to example embodiments and comparative examples 1 and 2;

FIGS. 5A, 5B, and 5C are CIE 1931 chromaticity diagrams representing a color reproducibility of a white light emitting device according to example embodiments and comparative examples 1 and 2;

FIG. 6 is a schematic, partially cutaway perspective view of a fluoride phosphor particle according to example embodiments;

FIG. 7 is a flowchart illustrating a method of manufacturing a fluoride phosphor, according to example embodiments;

FIG. 8 is a schematic, partially cutaway perspective view of a fluoride phosphor particle according to example embodiments;

FIGS. 9 and 10 are schematic cross-sectional views of a white light emitting device according to example embodiments;

FIGS. 11 and 12 are schematic cross-sectional views of white light source portions according to example embodiments;

FIG. 13 is a schematic cross-sectional view of a backlight according to example embodiments;

FIG. 14 is a schematic cross-sectional view of a backlight according to example embodiments;

FIG. 15 is a schematic cross-sectional view of a light emitting device employed in the backlight illustrated in FIG. 14;

FIGS. 16 and 17 are schematic cross-sectional views of backlights according to example embodiments; and

FIG. 18 is a schematic exploded perspective view of a display apparatus according to example embodiments.

### DETAILED DESCRIPTION OF THE EXAMPLE EMBODIMENTS

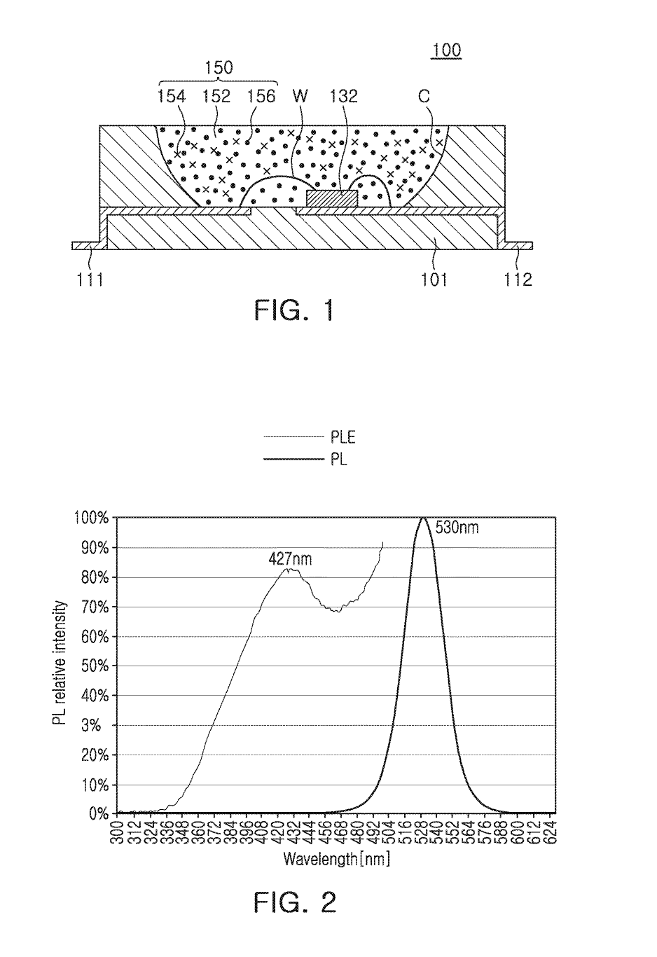

FIG. 1 is a schematic cross-sectional view of a white light emitting device according to example embodiments.

With reference to FIG. 1, a white light emitting device 100 includes a package body 101, a blue light emitting diode (LED) 132, and a resin encapsulation portion 150 disposed on the package body 101. The package body 101 is combined with a pair of lead frames 111 and 112 electrically connected to the blue LED 132, and includes a concave portion C providing a side-wall reflection structure.

The blue LED 132 is disposed on an upper surface of the package body 101, and may include an epitaxially-grown semiconductor layer. The blue LED 132 may emit light having a dominant wavelength in a range of 440 nm to 460 nm. In example embodiments, the dominant wavelength of the blue LED 132 may be within a range of 444 nm to 450 nm.

The resin encapsulation portion 150 is disposed within the concave portion C. The resin encapsulation portion 150 includes a transparent resin 152, a green quantum dot 154, and a red phosphor 156. At least a portion of the emitted light may be converted into green light and red light, respectively. The green quantum dot 154 and the red phosphor 156 may be dispersed within the transparent resin 152 to be disposed on a path of light emitted by the blue LED 132. For example, the transparent resin 152 may be formed of epoxy, silicone, modified silicone, urethane, oxetane, acryl, polycarbonate, polyimide, or a combination thereof.

The green quantum dot 154 may include a quantum dot having a core formed of a group II-VI compound and a group III-V shell. For example, the green quantum dot 154 may include at least one quantum dot selected from CdSe/CdS, CdSe/ZnS, CdSe/ZnS, PbS/ZnS, and InP/GaP/ZnS. The quantum dot may satisfy wavelength conditions by adjusting a diameter thereof.

When the green quantum dot 154 is excited by light emitted by the blue LED 132, the green quantum dot 154 employed in example embodiments may generate an emission spectrum having a peak wavelength in a range of 510 nm to 550 nm and a full width at half maximum of 45 nm or less. In example embodiments, to further improve color reproducibility, the peak wavelength of the green quantum dot 154 may be within a range of 530 nm to 545 nm. In addition, the full width at half maximum of the green quantum dot 154 may be 40 nm or less.

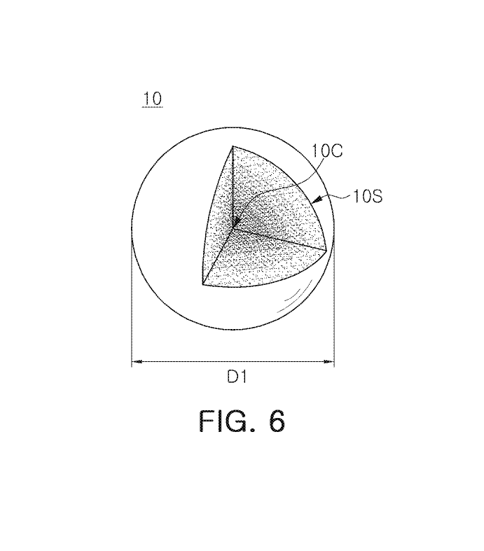

The red phosphor 156 may include a fluoride phosphor represented by empirical formula AₓMF_{y}:Mn⁴⁺. In this case, A is at least one selected from lithium (Li), sodium (Na), potassium (K), rubidium (Rb), and caesium (Cs), M is at least one selected from silicon (Si), titanium (Ti), zirconium (Zr), hafnium (Hf), germanium (Ge), and tin (Sn), and the empirical formula satisfies 2≦x≦3 and 4≦y≦7. The fluoride phosphor may be used in an improved form, for example, adding a protective coating layer thereto, to compensate vulnerability thereof to moisture. A detailed description thereof will be described in FIGS. 6 to 8.

When the red phosphor 156 is excited by light emitted by the blue LED 132, the red phosphor 156 employed in example embodiments may generate an emission spectrum having a peak wavelength in a range of 610 nm to 635 nm and a full width at half maximum of 30 nm or less. In example embodiments, to further improve color reproducibility, the emission spectrum of the red phosphor 156 may have the full width at half maximum of 10 nm or less.

A color reproduction range (i.e., a color gamut) may be defined as an area of a region surrounded by coordinates, when color obtained through red, green, and blue color filters is marked by a region in a CIE 1931 chromaticity diagram. In the case of the color reproduction of the white light emitting device 100 satisfying the conditions of a phosphor, a color reproduction region thereof may be 90% or more of a display control interface (DCI) region in the CIE 1931 chromaticity diagram. Additionally, the color reproduction of the white light emitting device 100 may be 95% or more based on a national television system committee (NTSC) region.

The package body 101 may include a polymer resin facilitating an injection molding process. For example, the resin may be an opaque resin or a resin containing powder having a high degree of reflectivity (for example, Al₂O₃). Alternatively, the package body 101 may include a ceramic substrate. In this case, heat dissipation may be facilitated through the package body 101. In example embodiments, the package body 101 may be a printed circuit board having a wiring pattern formed thereon.

The pair of lead frames 111 and 112 are disposed on the package body 101, and are electrically connected to the blue LED 132 to apply driving power thereto. The lead frames 111 and 112 are electrically connected to the blue LED 132 by a wire W. Alternatively, in a case in which the blue LED 132 has a flip-chip structure, the blue LED 132 may be directly connected to the lead frames 111 and 112 by a conductive bump.

Hereinafter, a function and an effect of the present inventive concept will be described in detail with reference to example embodiments.

### Example Embodiment 1

A white light emitting device was manufactured using an LED having a dominant wavelength of 446 nm as a blue LED and using green and red phosphors represented by CdSe/ZnS and K₂SiF₆:Mn⁴⁺, respectively. In addition, a wavelength conversion member was provided by combining green and red phosphors to obtain white light having the same color coordinates.

In Example Embodiment 1, the CdSe/ZnS phosphor employed as a green phosphor may be a green quantum dot having a ZnS shell and a CdSe core. Furthermore, photoluminescence excitation (PLE) and photoluminescence (PL) spectra thereof are illustrated in FIG. 2.

With reference to FIG. 2, a CdSe/ZnS quantum dot may have an excitation band having a peak wavelength of 427 nm. It can be confirmed that a PL spectrum of the CdSe/ZnS quantum dot having a peak wavelength of 530 nm and a narrow full width at half maximum of 34.6 nm satisfies conditions of the present inventive concept.

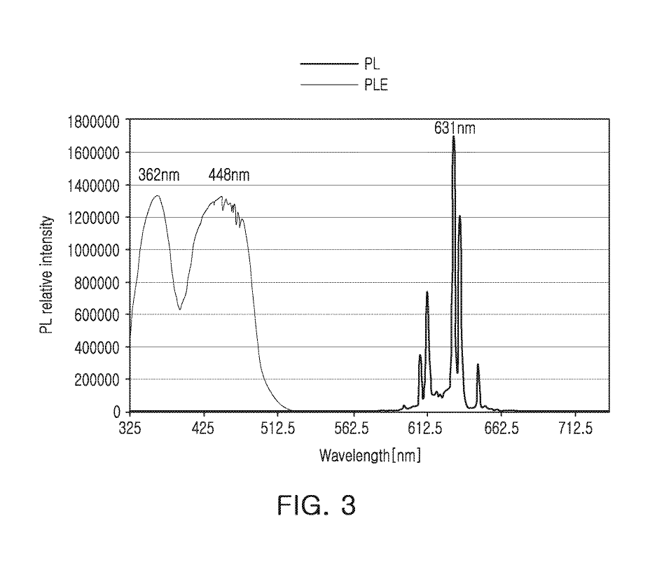

In Example Embodiment 1, the PLE and PL spectra of the K₂SiF₆:Mn⁴⁺ phosphor employed as a red phosphor are illustrated in FIG. 3.

With reference to FIG. 3, the K₂SiF₆:Mn⁴⁺ phosphor may include a first excitation band having a peak wavelength of 362 nm and a second excitation band having a peak wavelength of 448 nm. It can be understood that an excitation center is added by introducing Mn⁴⁺ as an activator, and thus another excitation band is added. The PL spectrum of the K₂SiF₆:Mn⁴⁺ phosphor may have a narrow full width at half maximum of 7 nm or less, along with a peak wavelength of 631 nm. As such, it can be confirmed that the K₂SiF₆:Mn⁴⁺ phosphor satisfies conditions of a red phosphor, proposed in example embodiments.

### Comparative Examples 1 and 2

In a similar manner to Example Embodiment 1, a white light emitting device was manufactured by providing a wavelength conversion member to obtain substantially the same white light as that of Example Embodiment 1, along with a blue LED chip of 446 nm, while the wavelength conversion member was formed in a manner different from Example Embodiment 1.

First of all, in the wavelength conversion member employed in Comparative Example 1, a β-SiAlON:Eu²⁺ phosphor having a peak wavelength of 540 nm and a full width at half maximum of 50 nm was used as a green phosphor, while a (Ca,Sr)AlSiN₃:Eu²⁺ phosphor having a peak wavelength of 620 nm and a full width at half maximum of 80 nm was used as a red phosphor.

In the wavelength conversion member employed in Comparative Example 2, a CdSe/ZnS phosphor (a peak wavelength of 542 nm and a full width at half maximum of 32 nm) the same as that of Example Embodiment 1 was used as a green phosphor, while a CdSe/ZnS quantum dot having a peak wavelength of 631 nm and a full width at half maximum of 31 nm was used as a red phosphor by adjusting size thereof.

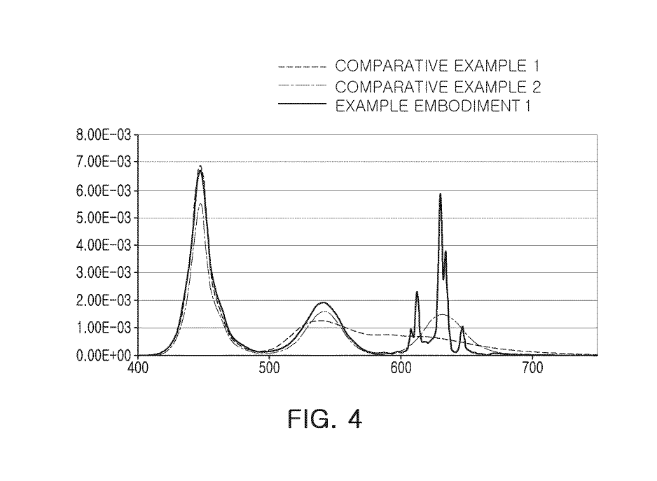

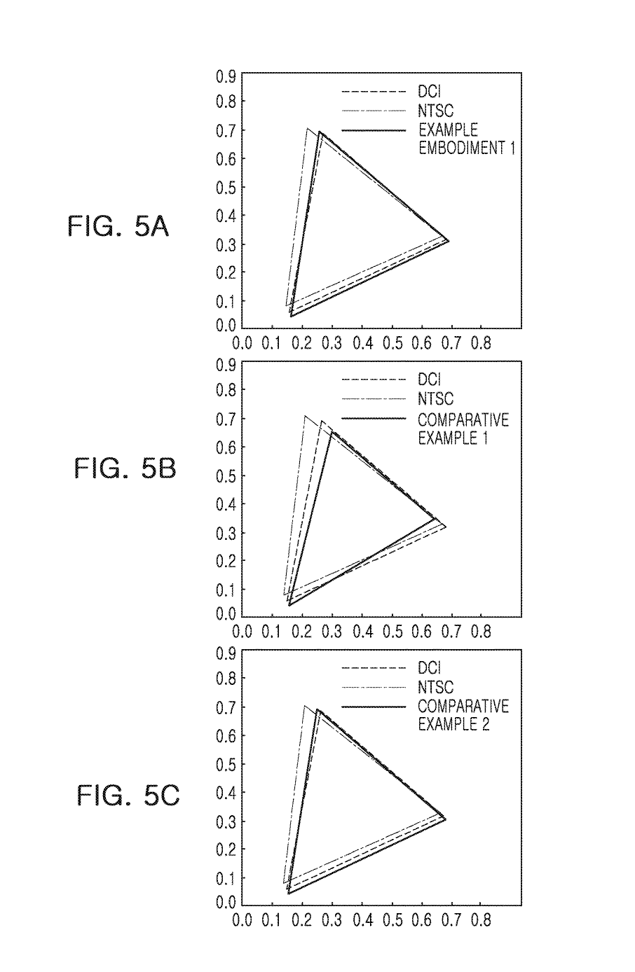

A PL spectrum of the white light emitting device, obtained from Comparative Examples 1 and 2 along with Example Embodiment 1, was measured as illustrated in FIG. 4. In addition, color gamuts that may be implemented by using red, green, and blue color filters (60-inch models by Sharp in 2012) were marked in the CIE 1931 chromaticity diagram as illustrated in FIGS. 5A to 5C.

With reference to FIG. 4, it can be confirmed that compared to Comparative Examples 1 and 2, the white light emitting device according to example embodiments represent the PL spectrum having a narrow full width at half maximum in a red region, as well as in a green region.

With reference to chromaticity diagrams in FIGS. 5A to 5C, along with color gamuts that may be implemented in Example Embodiment 1 and respective Comparative Examples 1 and 2, DCI-based and NTSC-based color gamuts are marked. Color reproduction in which an area of a color gamut defined by color coordinates corresponding to respective red, green, and blue vertexes covers a standard color gamut are represented in Table 1 below. Additionally, in the case that luminance of the white light emitting device according to Comparative Example 1 is 100%, relative luminance of Example Embodiment 1 and Comparative Example 2 is represented.

TABLE 1

| Classification | DCI (%) | NTSC (%) | Relative Luminance (%) |
|---|---|---|---|
| Example | 98.01 | 102.65 | 93% |
| Embodiment 1 | | | |
| Comparative | 82.70 | 80.46% | 100% |
| Example 1 | | | |
| Comparative | 97.68 | 101.87% | 85% |
| Example 2 | | | |

As such, the color reproduction of the white light emitting device according to Example Embodiment 1 are 98.01% based on a DCI color gamut and 102.65% based on an NTSC color gamut, higher than those of the white light emitting device in Comparative Examples 1 and 2. The white light emitting device according to Example Embodiment 1 may implement a color reproduction of 90% or more, in detail 95%, based on the DCI color gamut. In addition, it can be confirmed that the color reproduction of 95% or more, in detail 100%, may also be implemented in the NTSC color gamut.

In the meantime, it can be confirmed that in terms of luminance as well, the white light emitting device according to Example Embodiment 1 represents higher luminance than that of Comparative Example 2 in which green and red phosphors are implemented as a quantum dot. Because as in Comparative Example 2, a red quantum dot absorbs light in a green region, efficiency of converted green light is reduced, which may function as a reason therefor.

Color reproducibility may be significantly increased by using green and red phosphors satisfying conditions of a peak wavelength and a full width at half maximum and/or conditions of a phosphor composition, proposed in the present inventive concept.

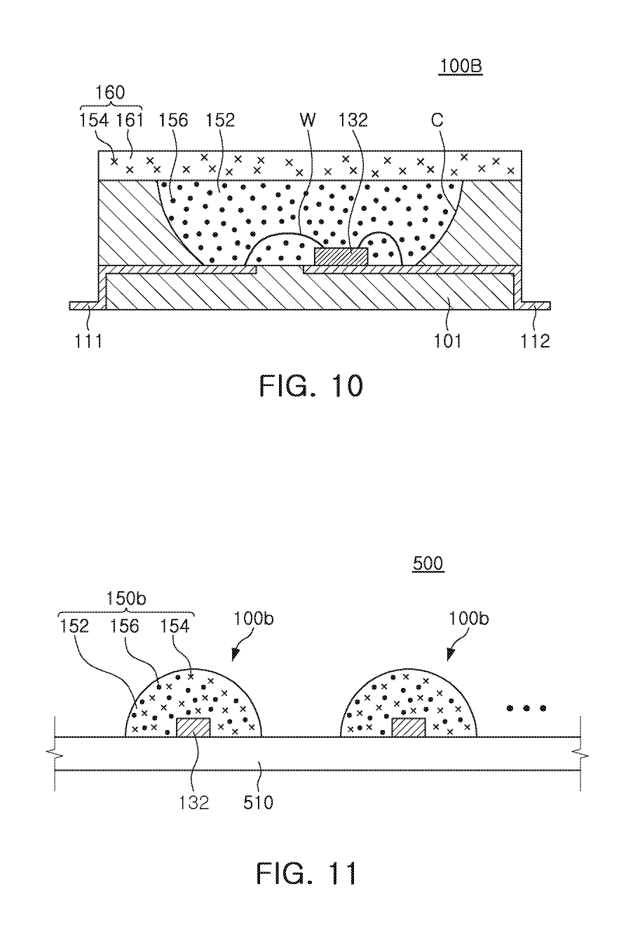

Phosphors employed in Example Embodiment 1 may have different vulnerability, and a method for complementing the vulnerability may be used. For example, a green phosphor, a quantum dot, may have vulnerability to heat. Therefore, to complement the characteristics, a structural change in a light emitting device or a display apparatus may be considered (see FIGS. 10, 14, and 15).

Because a fluoride phosphor used as a red phosphor may have vulnerability to moisture, an additional coating layer may be included to complement the characteristics. For example, the fluoride phosphor that may be employed in Example Embodiment 1 may be described with reference to FIGS. 6 to 8.

FIG. 6 is a schematic, partially cutaway perspective view of a fluoride phosphor particle according to example embodiments.

With reference to FIG. 6, a fluoride phosphor particle 10 according to example embodiments may include fluoride represented by empirical formula AₓMF_{y}:Mn⁴⁺, and the empirical formula may satisfy the conditions below:

1) A is at least one selected from Li, Na, K, Rb, and Cs;

2) M is at least one selected from Si, Ti, Zr, Hf, Ge, and Sn;

3) A compositional ratio (x) of A satisfies 2≦x≦3; and

4) A compositional ratio (y) of F satisfies 4≦y≦7.

The fluoride phosphor particle 10 represented by the empirical formula AₓMF_{y}:Mn⁴⁺ may include K₂SiF₆:Mn⁴⁺, K₂TiF₆:Mn⁴⁺, K₂SnF₆:Mn⁴⁺, Na₂TiF₆:Mn⁴⁺, Na₂ZrF₆:Mn⁴⁺, K₃SiF₇:Mn⁴⁺, K₃ZrF₇:Mn⁴⁺, and K₃SiF₅:Mn⁴⁺. The fluoride phosphor particle 10 may be excited by a wavelength of light form an ultraviolet region to a blue region to emit red light. For example, the fluoride phosphor particle 10 may provide a red phosphor absorbing excitation light having a peak wavelength in a range of 300 nm to 500 nm to emit light having a peak wavelength in a range of 610 nm to 635 nm.

In the case of the fluoride phosphor particle 10, a concentration of Mn⁴⁺, an activator, may be gradually reduced from a center 10C thereof to a surface 10S thereof. In the present specification, gradually reducing is defined as a concentration that is continuously reduced without a portion of the particle in which the concentration is uniformly maintained at a predetermined thickness or more. For example, the fluoride phosphor particle 10 may not have a uniform concentration of Mn⁴⁺ within a region thereof exceeding 10% of a particle size D1 in a direction from the center 10C of the particle to the surface 10S of the particle. An average reduction rate of Mn⁴⁺ concentration, for example, in an overall thickness of the fluoride phosphor particle 10, may be about 0.4 at. %/μm to about 0.8 at. %/μm. However, the concentration reduction rate, with respect to the overall thickness thereof, may not be uniform. For example, the reduction rate of Mn⁴⁺ concentration from the center 10C of the phosphor particle 10 to the surface 10S thereof may be within a range of about 0.1 at. %/μm to about 1.5 at. %/μm, depending on a region of the particle.

In addition, the Mn⁴⁺ concentration may be about 3 at. % to about 5 at. % in the center 10C of the fluoride phosphor particle 10, and may be about 1.5 at. % or less on the surface 10S of the fluoride phosphor particle 10. A difference in Mn⁴⁺ concentrations between the center 10C and the surface 10S of the fluoride phosphor particle 10 may be within a range of about 2 at. % to about 4 at. %. The particle size D1 of the fluoride phosphor particle 10 may be within a range of 5 μm to 25 μm.

Because the fluoride phosphor particle 10 according to example embodiments has a composition in which the Mn⁴⁺ concentration is reduced toward the surface 10S thereof, vulnerability of the fluoride phosphor particle 10 to moisture may be reduced and reliability thereof may be secured.

In other example embodiments, the fluoride phosphor particle may include fluoride containing Mn⁴⁺, while a coating layer surrounding the fluoride phosphor particle may include fluoride without Mn⁴⁺.

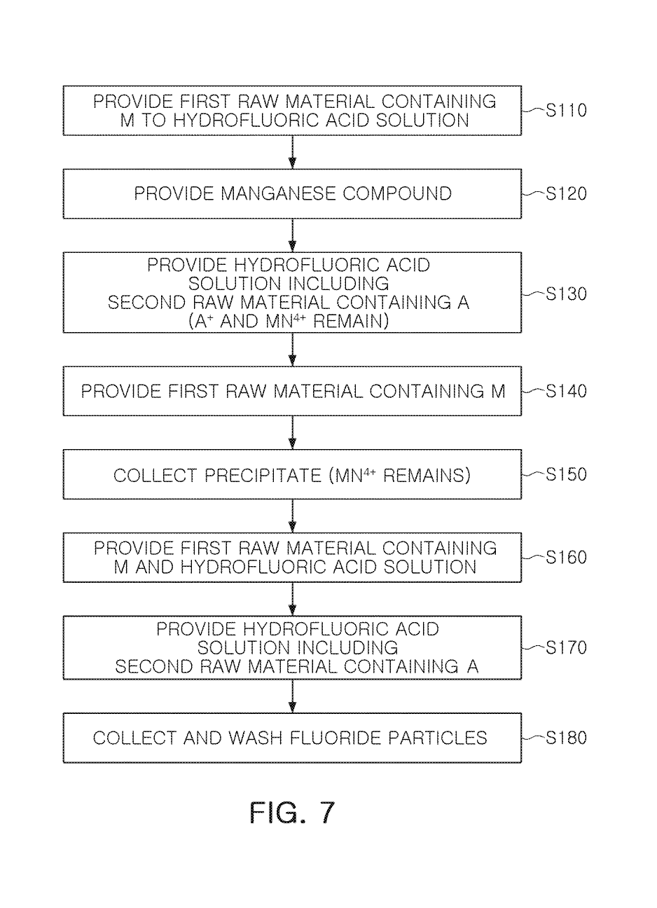

FIG. 7 is a flowchart illustrating a method of manufacturing a fluoride phosphor according to example embodiments.

With reference to FIG. 7, a method of manufacturing a fluoride phosphor includes providing a first raw material containing M to a hydrofluoric acid solution (S110), providing a manganese compound (S120), and providing a hydrofluoric acid solution including a second raw material containing A (S130). The method further includes providing a first raw material containing M (S140), collecting a formed precipitate (S150), and providing a first raw material containing M and a hydrofluoric acid solution (S160). The method further includes providing a hydrofluoric acid solution including a second raw material containing A (S170), and collecting and washing fluoride particles (S180).

The operations may be performed at room temperature, but the present inventive concept is not limited thereto.

First, a first raw material containing M may be added to a hydrofluoric acid solution in S110.

The first raw material may be at least one among HₓMF_{y}, AₓMF_{y} and MO₂, and for example may be H₂SiF₆ or K₂SiF₆. The first raw material may be added to the hydrofluoric acid solution, and may be stirred for several minutes to allow the first raw material to appropriately dissolve therein.

Subsequently, the manganese compound may be added to the hydrofluoric acid solution in S120.

Thereby, a first solution containing the first raw material containing M and the manganese compound may be produced. The manganese compound may be a compound containing Mn⁴⁺, and for example may have a composition of AₓMnF_{y}. For example, the manganese compound may have a composition of K₂MnF₆ by way of example. In a similar manner to an operation in S110, the manganese compound may be provided to the hydrofluoric acid solution in which the first raw material is dissolved, and may be stirred to allow the manganese compound to sufficiently dissolve therein.

Although example embodiments illustrate a case in which the first raw material containing M and the manganese compound are sequentially added to the hydrofluoric acid solution, the first solution may be produced in a different order therefrom. For example, according to other example embodiments, the manganese compound may first be provided to the hydrofluoric acid solution, and the first raw material containing M may be provided thereto.

Subsequently, the hydrofluoric acid solution including the second raw material containing A may be provided to the first solution in S130.

In detail, a second solution including the second raw material containing A may be provided to the first solution. The second raw material may be AHF₂, for example, KHF₂, and may be in a saturated solution state or powder form.

As concentrations of respective raw materials approach a solubility limit of the hydrofluoric acid solution, an orange precipitate may be formed. The precipitate may be Mn⁴⁺-activated fluoride (AₓMF_{y}:Mn⁴⁺). For example, when H₂SiF₆ and KHF₂ are used as the first and second raw materials, and K₂MnF₆ is used as a compound containing Mn⁴⁺, the precipitate may be fluoride represented by K₂SiF₆:Mn⁴⁺.

In S130, A⁺ and Mn⁴⁺ not reacting with the precipitates may remain in the solution.

An amount of the second raw material may be divided and added at an interval corresponding to a time for reaction thereof, and thus a particle size of fluoride may be controlled. An average particle size and particle size distribution may be controlled by adjusting at least one among an addition number, an addition amount, an addition interval, and the like. For example, when the second raw material is divided into four parts and provided, fluoride seeds may be formed by a primarily-added second raw material, the seeds may be grown by secondarily and thirdly added second raw materials, and precipitation of the grown seeds may be induced by a fourthly added second raw material.

Subsequently, the first raw material containing M may be added to the solution in S140.

The first raw material may be the same material as the material used in S110, but is not limited thereto. The first raw material may be at least one among HₓMF_{y} and AₓMF_{y}, and for example may be H₂SiF₆ or K₂SiF₆. The first raw material may be added to the solution, and may be stirred for several minutes to appropriately dissolve therein.

In S140, the added first raw material may react with A⁺ and Mn⁴⁺ remaining in the solution described above to allow the precipitate to grow. Thus, in a region formed in S140, a Mn⁴⁺ concentration may be relatively low. For example, in a case in which K₂SiF₆:Mn⁴⁺ is synthesized in S130, when a H₂SiF₆ solution is additionally supplied in S140, the H₂SiF₆ solution reacts with residual KHF₂ and Mn⁴⁺ to create K₂SiF₆, which may be grown in a shell form on a surface of the fluoride formed in S130.

Although in example embodiments, a case in which the second raw material remains after S130 is illustrated, the first raw material may remain. In this case, the second raw material containing A may be additionally provided in S140, rather than the first raw material.

An amount of the first raw material provided in S140 may be smaller than that of the first raw material provided to the first solution in S110, and for example, a volume of the first raw material provided in S140 may be within a range equal to 15% to 25% of that of the first raw material provided to the first solution in S110.

Subsequently, the formed precipitate may be collected in S150.

The precipitate may be formed by having started to settle in S130, and Mn⁴⁺ remaining on a surface of the precipitate may also be collected, while the second raw material such as A⁺ may be almost entirely consumed in S140, and thus may not remain.

In S150, hydrofluoric acid may be removed, and the precipitate may be collected, and thus Mn⁴⁺ remaining in the hydrofluoric acid solution may be removed together therewith. Thus, because only a small amount of Mn⁴⁺ remaining on the precipitate surface may be used at the time of a reaction of a subsequent process, a Mn⁴⁺ concentration in a phosphor region grown subsequently may be further decreased.

Next, the first raw material containing M and the hydrofluoric acid solution may be added to the precipitate in S160. Thereby, a third solution may be produced.

The first raw material may be the same material as the material used in S110 and S140, but is not limited thereto.

The amount of the first raw material provided in S160 may be smaller than that of the first raw material provided to the first solution in S110, and for example, the volume of the first raw material provided in S160 may be within a range equal to 15% to 25% of that of the first raw material provided to the first solution in S110.

Subsequently, the hydrofluoric acid solution including the second raw material containing A may be provided to the third solution in S170.

For example, the second solution, a hydrofluoric acid solution including the second raw material containing A, may be re-provided to the third solution. The second solution may contain the same second raw material as that used in S130, but is not limited thereto. In S170, an amount of the second raw material may be divided and provided at an interval corresponding to a time for reaction thereof, and thus a particle size of a fluoride particle to be formed may be controlled.

The amount of the second raw material provided in S170 may be smaller than that of the second raw material provided to the first solution in S130, and for example, a weight of the second raw material provided in S170 may be within a range equal to 40% to 60% of that of the second raw material provided to the first solution in S130.

The second raw material may react with Mn⁴⁺ remaining together with the precipitate and the first raw material within the third solution, so that fluoride particles may be formed in a shell form on the fluorides of the precipitate. To be discernible from the precipitate formed in S150, a final phosphor particle formed in S170 may be referred to as a fluoride particle for convenience of explanation, but a fluoride phosphor according to example embodiments may include a fluoride material that is grown from the precipitate and is finally formed in S170, but is not limited to a name referred to in respective operations.

Subsequently, fluoride particles may be collected and washed in S180.

The washing process may be performed using a hydrofluoric acid solution and/or an acetone solution as a washing solution. The washing process may be performed by stirring the precipitate using, for example, about 49% of high concentration hydrofluoric acid aqueous solution, and thus, impurities present on the fluoride particles, residual first and second raw materials, and the like may be removed. In example embodiments, the washing process may also be performed a plurality of times using different cleansing solutions.

Then, a fluoride phosphor according to example embodiments of the present inventive concept may be obtained by drying washed fluoride particles. The fluoride particles may be selectively dried, and a heat treatment process thereof at a temperature of about 100° C. to about 150° C. may further be performed.

The fluoride phosphor in which a content of manganese is gradually reduced toward a surface thereof may be produced through the processes as described above. According to example embodiments, a manganese compound containing Mn⁴⁺ may be provided once in S120, the addition number and the addition amount of the first and second raw materials may be adjusted, and thus phosphor particles may be grown in an environment in which a Mn⁴⁺ concentration is continuously reduced.

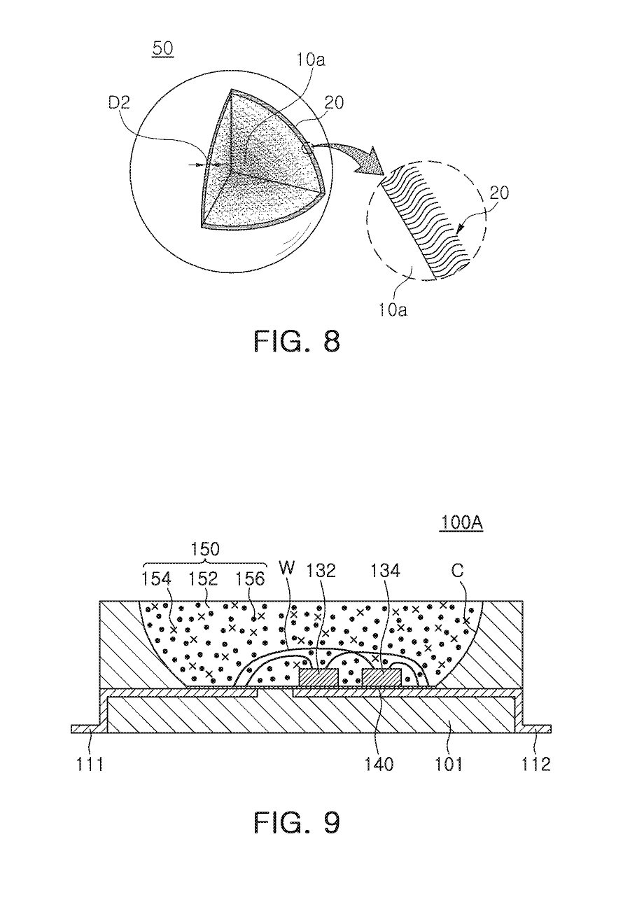

FIG. 8 is a schematic, partially cutaway perspective view of a fluoride phosphor particle according to example embodiments.

With reference to FIG. 8, a fluoride phosphor particle 50 includes a fluoride particle 10a represented by AₓMF_{y}:Mn⁴⁺ and organic materials 20 adsorbed onto a surface of the fluoride particle 10a, according to example embodiments.

The fluoride particle 10a may be a core of the fluoride phosphor particle 50, and may have the same configuration as the fluoride phosphor particle 50 illustrated in FIG. 6. Thus, the fluoride particle 10a may have a composition in which a concentration of Mn⁴⁺ is gradually reduced from a center thereof to a surface thereof. For instance, the fluoride phosphor particle 50 in example embodiments may have a structure in which the organic materials 20 are added to the fluoride phosphor particle 10 illustrated in FIG. 8.

The organic materials 20 may be physically adsorbed onto a surface of the fluoride particle 10a to protect the fluoride particle 10a. The organic materials 20 may be materials having a hydrophobic tail. Thus, a surface of the fluoride phosphor particle 50 may have hydrophobicity to have further increased moisture resistance.

For example, the organic materials 20 may have at least one functional group between a carboxylic group (—COOH) and an amino group (—NH₂), and may include an organic compound having carbon numbers 4 to 18. In detail, the organic materials 20 may be fatty acids, such as an oleic acid having a composition of C₁₈H₃₄O₂. In this case, because a length of one organic material 20 may be several nanometers or less, a thickness D2 of a coating layer by the organic material 20 may also be within a range of several nanometers to tens of nanometers. For example, the thickness D2 of the coating layer may be 5 nm or less.

FIG. 9 is a schematic cross-sectional view of a white light emitting device according to example embodiments.

With reference to FIG. 9, a white light emitting device 100A includes a package body 101 containing a concave portion C, a blue LED 132 and a near ultraviolet LED 134 that are disposed on the package body 101, a protective layer 140, and a resin encapsulation portion 150.

The white light emitting device 100A includes a pair of lead frames 111 and 112 electrically connected to the blue LED 132 and the near ultraviolet LED 134, and a conductive wire W connecting the blue LED 132 and the near ultraviolet LED 134 to the lead frames 111 and 112.

Different from the white light emitting device 100 illustrated in FIG. 1, the white light emitting device 100A illustrated in FIG. 9 further includes the near ultraviolet LED 134. Because, as illustrated in FIG. 3, a red phosphor 156 employed in example embodiments forms an excitation band in a near ultraviolet, sufficient green light may be obtained from the red phosphor 156 having relatively low efficiency by further employing the near ultraviolet LED 134.

The red phosphor 156 employed in example embodiments may use fluoride phosphors illustrated in FIGS. 6 to 8. The protective layer 140 may be disposed on at least one surface of the resin encapsulation portion 150. In a case in which a fluoride phosphor is used as a red phosphor 156, the protective layer 140 may protect the fluoride phosphor from an external environment, in detail, moisture, and may secure reliability of the white light emitting device 100A. The protective layer 140 may be formed of a moisture resistive material capable of preventing permeation of moisture.

In example embodiments, although the protective layer 140 is disposed on a lower surface of the resin encapsulation portion 150, for example, between the resin encapsulation portion 150 and the package body 101, the disposition of the protective layer 140 may be variously changed according to example embodiments. For example, the protective layer 140 may be disposed on both of an upper surface and the lower surface of the resin encapsulation portion 150, or may be disposed to encompass an entirety of the resin encapsulation portion 150.

FIG. 10 is a schematic cross-sectional view of a white light emitting device according to example embodiments.

With reference to FIG. 10, a white light emitting device 100B according to example embodiments may be construed as being similar to the white light emitting device 100 illustrated in FIG. 1 except that the green quantum dot 154 is included in a separate film 160. In addition, components of example embodiments may be construed with reference to a description of components the same as or similar to those of the white light emitting device 100 illustrated in FIG. 1 as long as there is no opposite description thereto.

Because the green quantum dot 154 is a quantum dot vulnerable to heat, the green quantum dot 154 may be disposed to be spaced apart from the blue LED 132, a heat source, to prevent heat from deteriorating reliability thereof.

In example embodiments, the green quantum dot 154 may be included in a separately provided wavelength conversion film 160. The wavelength conversion film 160 includes a transparent resin 161 in which the green quantum dot 154 is dispersed. The transparent resin 161 may be formed of a material such as epoxy, silicone, modified silicone, urethane, oxetane, acryl, polycarbonate, polyimide, or a combination thereof.

The wavelength conversion film 160 may be disposed on a path of emitted light. In example embodiments, the wavelength conversion film 160 may be disposed to allow the resin encapsulation portion 150 to cover the package body 101.

In the structure, light emitted by the blue LED 132 may excite the red phosphor 156 in the resin encapsulation portion 150 and the green quantum dot 154 in the wavelength conversion film 160, and thus the white light emitting device 100B may obtain white light. Because the green quantum dot 154 may be disposed in the wavelength conversion film 160, the green quantum dot 154 may be disposed to be spaced apart from the blue LED 132, a heat source, thus maintaining reliability. The red phosphor 156 may use fluoride phosphors illustrated in FIGS. 6 to 8.

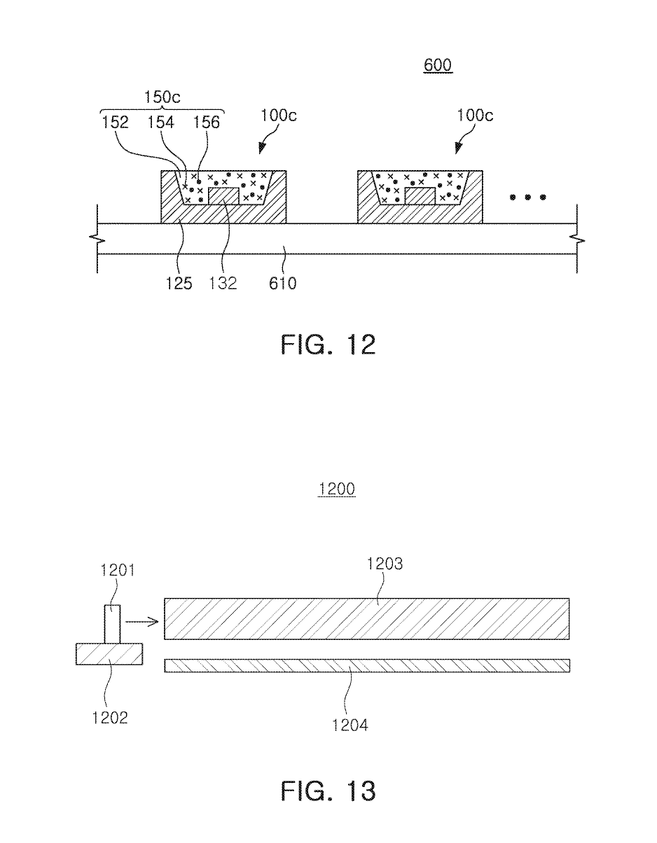

FIGS. 11 and 12 are schematic cross-sectional views of white light source portions according to example embodiments.

With reference to FIG. 11, a light source portion 500 for a liquid crystal display (LCD) backlight includes a circuit board 510 and a plurality of white light emitting devices 100b mounted on the circuit board 510.

A conductive pattern connected to the white light emitting devices 100b may be formed on the circuit board 510. Each of white light emitting devices 100b have a structure in which the blue LED 132 is directly mounted on the circuit board 510 in a chip-on-board (COB) scheme different from the case of the white light emitting device 100 illustrated in FIG. 1. In detail, the white light emitting devices 100b do not have a separate reflective wall, and a resin encapsulation portion 150b has a semispherical shape having a lens function to exhibit a wide-beam angle. The wide-beam angle may contribute to a reduction in a thickness or a width of an LCD display. In the resin encapsulation portion 150b, the green quantum dot 154 and the red phosphor 156, satisfying a condition detailed in example embodiments, are included.

With reference to FIG. 12, a white light source portion 600 for an LCD backlight includes a circuit board 610 and a plurality of white light emitting devices 100c mounted on the circuit board 610.

Each of the white light emitting devices 100c includes the blue LED 132 mounted in the concave portion C of the package body 125 and a resin encapsulation portion 150c encapsulating the blue LED 132. In the resin encapsulation portion 150c, the green quantum dot 154 and the red phosphor 156, satisfying the condition detailed in example embodiments, are dispersed.

FIG. 13 is a schematic cross-sectional view of a backlight according to example embodiments.

With reference to FIG. 13, a backlight 1200 includes a light guide panel 1203 and a light source portion emitting light in a direction lateral to the light guide panel 1203. The emitted light may be incident onto the light guide panel 1203 to be converted into a form of surface light source. The light source portion includes a circuit board 1202 and a white light emitting device 1201 mounted on the circuit board 1202. The light source portion may be a light source portion having a shape similar to those illustrated in FIGS. 11 and 12. Alternatively, the white light emitting device 1201 may be a white light emitting device described in example embodiments. The backlight 1200 includes a reflective layer 1204 disposed below the light guide panel 1203 so that light passing through the light guide panel 1203 may be discharged in an upward direction.

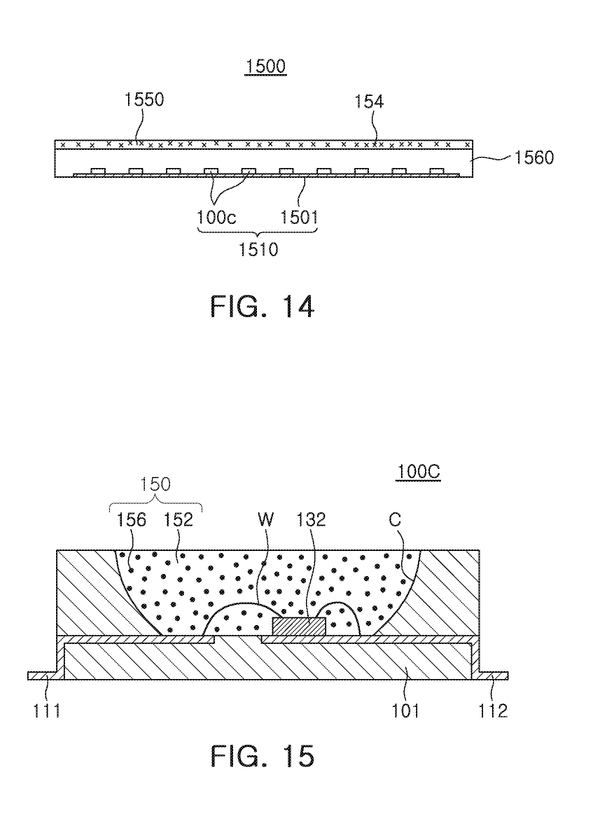

The backlight 1200 employed in example embodiments represents an example in which white light emitting devices (FIGS. 1, 9, and 10) are employed. In example embodiments, a light emitting device may not include an entirety of phosphors, and at least one phosphor may be disposed in a different component of a backlight. A phosphor disposed in a different component may be manufactured to be a separate wavelength conversion sheet and disposed on the path of emitted light. Example embodiments are illustrated in FIGS. 14 to 17.

FIG. 14 is a schematic cross-sectional view of a backlight according to example embodiments, and FIG. 15 is a schematic cross-sectional view of a light emitting device that may be employed in the backlight illustrated in FIG. 14.

A backlight 1500 illustrated in FIG. 14 may be an example of a direct-type backlight. The backlight 1500 includes a wavelength conversion sheet 1550, a light source portion 1510 disposed below the wavelength conversion sheet 1550, and a bottom case 1560 receiving the light source portion 1510. The light source portion 1510 includes a printed circuit board 1501 and a plurality of light emitting devices 100c mounted on the printed circuit board 1501.

As illustrated in FIG. 14, the wavelength conversion sheet 1550 is disposed on the bottom case 1560. The wavelength conversion sheet 1550 includes the green quantum dot 154 described in example embodiments. As described above, because the green quantum dot 154 is vulnerable to heat, reliability thereof may be maintained in such a manner that the green quantum dot 154 may be disposed to be sufficiently spaced apart from the light emitting device 100c using the wavelength conversion sheet 1550. The green quantum dot 154 disposed in the wavelength conversion sheet 1550 may allow a wavelength of at least a portion of light emitted by the light source portion 1510 to be converted.

As illustrated in FIG. 15, a light emitting device 100C employed in example embodiments includes the blue LED 132 and the resin encapsulation portion 150 surrounding the blue LED 132 in a manner similar to FIG. 1. In example embodiments, the resin encapsulation portion 150 includes the red phosphor 156 without a green quantum dot.

In the structure, the green quantum dot may be disposed to be spaced apart from the light emitting device 100c, thus preventing heat from deteriorating reliability thereof. In addition, the red phosphor may be disposed in a separate package, thus allowing usage of the red phosphor not to be increased.

Different from example embodiments, the wavelength conversion sheet 1550 may be disposed on a different component. For example, the wavelength conversion sheet 1550 may be provided with additional light diffusion plate or light guide panel to be disposed thereon. In the same manner as example embodiments, the wavelength conversion sheet 1550 may be manufactured and used as a separate sheet, or may be provided in a form integrated with a different component such as a light diffusion plate.

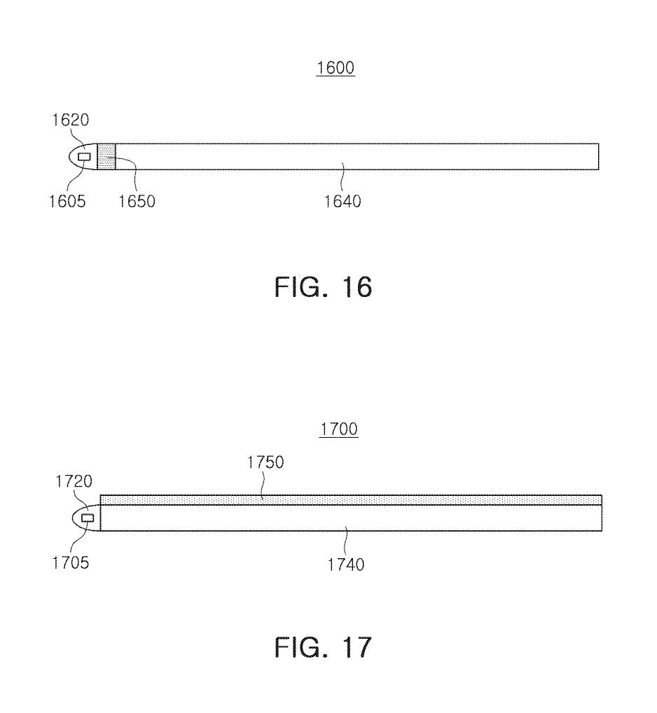

In a manner similar to example embodiments, backlights 1600 and 1700 illustrated in FIGS. 16 and 17 may convert light in such a manner that a wavelength conversion material (the green quantum dot and the red phosphor) may not be directly disposed in light emitting devices 1605 and 1705, but may be disposed to be spaced apart from the light emitting devices 1605 and 1705, heat sources, in a different position in the backlights 1600 and 1700.

With reference to FIGS. 16 and 17, the backlight 1600 or 1700 may be provided as an edge-type backlight, and includes a wavelength conversion sheet 1650 or 1750, a light guide panel 1640 or 1740, a reflector 1620 or 1720 disposed on a side of the light guide panel 1640 or 1740, and the light emitting device 1605 or 1705 as a light source.

Light emitted by the light emitting device 1605 or 1705 may be guided to an inner portion of the light guide panel 1640 or 1740 by the reflector 1620 or 1720. In the backlight 1600 illustrated in FIG. 16, the wavelength conversion sheet 1650 is disposed between the light guide panel 1640 and the light emitting device 1605. In the backlight 1700 illustrated in FIG. 17, the wavelength conversion sheet 1750 is disposed on a light emission surface of the light guide panel 1740.

In a manner similar to the wavelength conversion sheet 1550 described in FIG. 14, the wavelength conversion sheet 1650 or 1750 used therein may only include the green quantum dot, but not limited thereto. Furthermore, the wavelength conversion sheet 1650 or 1750 may include the red phosphor as well as the green quantum dot.

In the case that the wavelength conversion sheet 1650 or 1750 may only include the green quantum dot, the light emitting device 1605 or 1705 may have a shape including only the red phosphor 156 along with the blue LED 132 in a manner similar to an example illustrated in FIG. 15. In the meantime, in the case that wavelength conversion sheet 1650 or 1750 may include both of the green quantum dot and the red phosphor, the light emitting device 1605 or 1705 may only include the blue LED 132 without phosphors.

A light source of a backlight according to example embodiments may not employ a light emitting device having a separate package body, but a COB-type light source portion illustrated in FIG. 11.

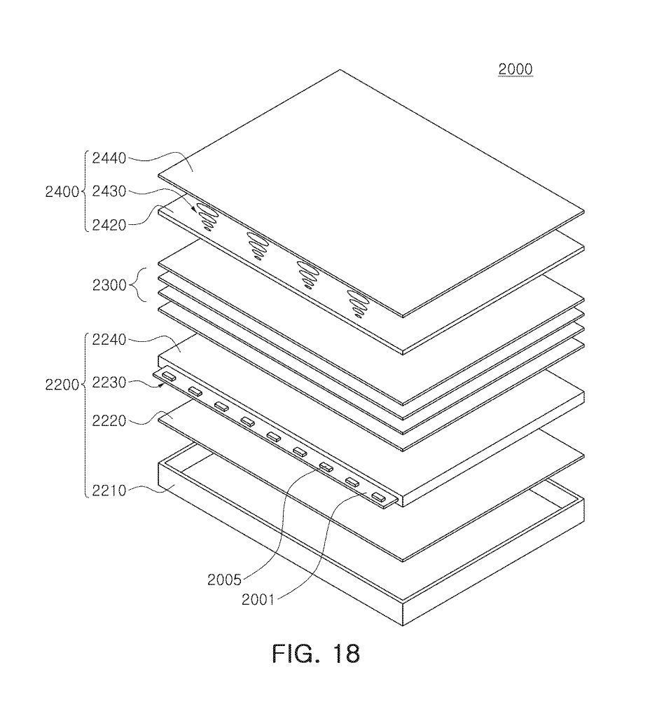

FIG. 18 is a schematic exploded perspective view of a display apparatus according to example embodiments.

With reference to FIG. 18, a display apparatus 2000 includes a backlight 2200, optical sheets 2300, and an image display panel 2400 such as a liquid crystal panel.

The backlight 2200 includes a bottom case 2210, a reflective plate 2220, a light guide panel 2240, and a light source portion 2230 provided on at least one side of the light guide panel 2240. The light source portion 2230 includes a printed circuit board 2001 and light emitting devices 2005. The light emitting device may be a white light emitting device according to example embodiments, or the light source portion illustrated in FIG. 11. The light emitting device 2005 employed in example embodiments may be a side view-type light emitting device that is mounted on a side surface adjacent to the light emission surface.

In addition, in example embodiments, the backlight 2200 may be replaced by any one among the backlights 1200, 1500, 1600, and 1700, illustrated in FIGS. 13 to 17, respectively. In detail, the light emitting device may be a white light emitting device including both of the green quantum dot and the red phosphor. However, in example embodiments (FIGS. 14 to 17), at least the green quantum dot may be disposed in a different component (for example, a light guide panel) of the backlight, or may be manufactured to be included in a separate wavelength conversion sheet and disposed on the path of emitted light (for example, a surface of the light guide panel).

The optical sheets 2300 are disposed between the light guide panel 2240 and the image display panel 2400, and may include several types of sheets such as a diffusion sheet, a prism sheet, or a protective sheet.

The image display panel 2400 may display an image using light emitted through the optical sheets 2300. The image display panel 2400 includes an array substrate 2420, a liquid crystal layer 2430, and a color filter layer 2440. The array substrate 2420 may include pixel electrodes disposed in a matrix form, thin film transistors applying a driving voltage to the pixel electrodes, and signal lines allowing for operation of the thin film transistors.

The color filter layer 2440 may include a transparent substrate, a color filter, and a common electrode. The color filter layer 2440 may include filters allowing a wavelength of light to pass therethrough among white light emitted by the backlight 2200. The liquid crystal layer 2430 may be re-arranged by an electric field formed between the pixel electrodes and the common electrode to adjust a light transmitting rate. Light of which a light transmitting rate has been adjusted may pass through the color filter of the color filter layer 2440, thereby displaying an image. The image display panel 2400 may further include a driving circuit processing an image signal, and the like.

According to the display apparatus 2000 in example embodiments, a color reproduction implemented in light passing through the color filter may be significantly increased. A color reproduction region of the display apparatus may cover 90% or more of the DCI region in the CIE 1931 chromaticity diagram, and may also cover 95% or more based on the NTSC region.

As set forth above, according to example embodiments, a white light emitting device may implement colors having a high color gamut by combining a blue LED with a green phosphor and a red phosphor, satisfying the full width at half maximum and the peak wavelength described above. Furthermore, various types of display apparatuses that may cover 90% or more based on DCI may be provided.

While example embodiments have been shown and described above, it will be apparent to those skilled in the art that modifications and variations could be made without departing from the scope of the present inventive concept as defined by the appended claims.

1. A white light emitting device comprising:
a blue light emitting diode (LED) emitting first light having a dominant wavelength in a range of 440 nm to 460 nm;
a first wavelength-conversion material disposed on a path of the emitted first light and converting a first portion of the emitted first light into green light; and
a second wavelength-conversion material disposed on the path of the emitted first light and converting a second portion of the emitted first light into red light,
wherein the first wavelength-conversion material comprises a quantum dot comprising a core formed of a group III-V compound and a shell formed of a group II-VI compound,
the second wavelength-conversion material comprises a fluoride phosphor represented by empirical formula AₓMF_{y}:Mn⁴⁺, A being at least one selected from lithium (Li), sodium (Na), potassium (K), rubidium (Rb), and caesium (Cs), M being at least one selected from silicon (Si), titanium (Ti), zirconium (Zr), hafnium (Hf), germanium (Ge), and tin (Sn), and the empirical formula satisfying 2≦x≦3 and 4≦y≦7, and
the white light emitting device emits white light of which a color reproduction region covers 90% or more of a display control interface region in a CIE 1931 chromaticity diagram.

2. The white light emitting device of claim 1, wherein the first wavelength-conversion material has a peak wavelength in a range of 530 nm to 545 nm, and
the second wavelength-conversion material has a full width at half maximum of 10 nm or less.

3. The white light emitting device of claim 1, wherein the first wavelength-conversion material comprises at least one quantum dot among CdSe/CdS, CdSe/ZnS, CdSe/ZnS, PbS/ZnS, and InP/GaP/ZnS, and
the second wavelength-conversion material comprises at least one fluoride phosphor represented by K₂SiF₆:Mn⁴⁺.

4. The white light emitting device of claim 1, wherein the fluoride phosphor comprises a fluoride particle of which a concentration of Mn⁴⁺ is gradually reduced from a center to a surface.

5. The white light emitting device of claim 1, wherein the fluoride phosphor comprises a fluoride particle comprising a surface on which an organic material having hydrophobicity is physically absorbed.

6. The white light emitting device of claim 1, further comprising a resin encapsulation portion surrounding the blue LED and containing the first wavelength-conversion material and the second wavelength-conversion material.

7. The white light emitting device of claim 1, further comprising:
a resin encapsulation portion surrounding the blue LED and containing the second wavelength-conversion material; and
a wavelength conversion film disposed on the resin encapsulation portion and containing the first wavelength-conversion material.

8. The white light emitting device of claim 1, further comprising a near ultraviolet LED emitting second light having a dominant wavelength in a range of 360 nm to 420 nm.

9. A white light emitting device comprising:
a blue light emitting diode (LED) emitting first light having a dominant wavelength in a range of 440 nm to 460 nm;
a green quantum dot disposed on a path of the emitted first light and converting a first portion of the emitted first light into second light having a peak wavelength in a range of 510 nm to 550 nm and having a full width at half maximum of 45 nm or less; and
a red phosphor disposed on the path of the emitted first light and converting a second portion of the emitted first light into third light having a peak wavelength in a range of 610 nm to 635 nm and having a full width at half maximum of 30 nm or less.

10. The white light emitting device of claim 9, wherein the green quantum dot has a peak wavelength in a range of 530 nm to 545 nm.

11. The white light emitting device of claim 10, wherein the green quantum dot comprises a quantum dot comprising a core formed of a group III-V compound and a shell formed of a group II-VI compound.

12. The white light emitting device of claim 9, wherein the red phosphor has a full width at half maximum of 10 nm or less.

13. The white light emitting device of claim 12, wherein the red phosphor comprises a fluoride phosphor represented by empirical formula AₓMF_{y}:Mn⁴⁺, A being at least one selected from Li, Na, K, Rb, and Cs, M being at least one selected from Si, Ti, Zr, Hf, Ge, and Sn, and the empirical formula satisfying 2≦x≦3 and 4≦y≦7.

14. The white light emitting device of claim 9, wherein the white light emitting device emits white light of which a color reproduction region covers 90% or more of a display control interface region in a CIE 1931 chromaticity diagram.

15. A display apparatus comprising:
an image display panel comprising a color filter layer comprising red, green, and blue color filters;
a backlight disposed on the image display panel and comprising light sources, each of the light sources comprising a blue light emitting diode (LED) emitting first light having a dominant wavelength in a range of 440 nm to 460 nm;
a green quantum dot disposed on a path of the emitted first light and converting a first portion of the emitted first light into second light having a peak wavelength in a range of 510 nm to 550 nm and having a full width at half maximum of 45 nm or less; and
a red phosphor disposed on the path of the emitted first light and converting a second portion of the emitted first light into third light having a peak wavelength in a range of 610 nm to 635 nm and having a full width at half maximum of 30 nm or less,
wherein each of the light sources emits, through the color filter layer, fourth light of which a color reproduction region covers 90% or more of a display control interface region in a CIE 1931 chromaticity diagram.

16. The display apparatus of claim 15, wherein the green quantum dot comprises a quantum dot comprising a core formed of a group III-V compound and a shell formed of a group II-VI compound, and
the red phosphor comprises a fluoride phosphor represented by empirical formula AₓMF_{y}:Mn⁴⁺, A being at least one selected from Li, Na, K, Rb, and Cs, M being at least one selected from Si, Ti, Zr, Hf, Ge, and Sn, and the empirical formula satisfying 2≦x≦3 and 4≦y≦7.

17. (canceled)

18. The display apparatus of claim 15, wherein each of the light sources further comprises:
a resin encapsulation portion surrounding the blue LED and containing the red phosphor; and
a wavelength conversion film disposed on the path of the emitted first light on the resin encapsulation portion and containing the green quantum dot.

19. The display apparatus of claim 15, the light sources are configured to include the red phosphor, and
the backlight further comprises a wavelength conversion sheet containing the green quantum dot.

20. The display apparatus of claim 19, wherein the backlight further comprises a light guide panel, and
the wavelength conversion sheet is disposed on or within the light guide panel.

21. The display apparatus of claim 15, wherein the color reproduction region of the fourth light covers 95% or more of a national television system committee region in the CIE 1931 chromaticity diagram.

22.-23. (canceled)
